(19) United States
(12) Patent Application Publication
(10) Pub. No.: US 2015/0048726 A1
(43) Pub. Date: Feb. 19, 2015

(54) MOUNTING APPARATUS FOR BRACKET

(71) Applicants: HONG FU JIN PRECISION INDUSTRY (WUHAN) CO., LTD., Wuhan (CN); HON HAI PRECISION INDUSTRY CO., LTD., New Taipei (TW)

(72) Inventors: LIN DING, Wuhan (CN); LIANG-CHIN WANG, New Taipei (TW); YU-MING XIAO, Wuhan (CN); ZHI-JUN FU, Wuhan (CN)

(73) Assignees: HON HAI PRECISION INDUSTRY CO., LTD., New Taipei (TW); HONG FU JIN PRECISION INDUSTRY (WUHAN) CO., LTD., Wuhan (CN)

(21) Appl. No.: 14/459,832

(22) Filed: Aug. 14, 2014

(30) Foreign Application Priority Data
Aug. 14, 2013 (CN) 201310352657X

(51) Int. Cl. H05K 7/14; H05K 7/18; H05K 5/02

(52) U.S. Cl. CPC H05K 7/14; H05K 5/0217; H05K 7/183
USPC 312/223.2

(57) ABSTRACT

Mounting apparatus for bracket can include a computer case, a supporting bracket, and a locating bracket mounted to the computer case. The computer case can include a first limiting slot and two engaging portions. The supporting bracket can include an elastic tab, two cutouts and two second limiting slots. The second limiting slot can include a guiding slot and a receiving slot. The locating bracket can include two resisting portions. The resisting portion can include a first supporting portion and a second supporting portion. The elastic tab can be rotated to slide in the first limiting slot. The two engaging portions can be locked in the cutouts. The second supporting portion can slide in the guiding slot from the receiving slot. The first supporting portion can be received in the receiving slot and can resist against the connecting plate.

### CROSS-REFERENCE TO RELATED APPLICATIONS

This application claims priority to Chinese Patent Application No. 201310352657.X filed on Aug. 14, 2013 in the China Intellectual Property Office, the contents of which are incorporated by reference herein.

### FIELD

The subject matter herein generally relates to a mounting apparatus for brackets.

### BACKGROUND

A conventional personal computer includes a number of I/O ports which can be located on a supporting bracket of the computer. A conventional supporting bracket can be mounted to the computer by a number of screws.

### BRIEF DESCRIPTION OF THE DRAWINGS

Implementations of the present technology will now be described, by way of example only, with reference to the attached figures, wherein:

FIG. 1 is an exploded view of an embodiment of a mounting apparatus for a bracket.

FIG. 2 is an exploded view of the mounting apparatus for the bracket, viewed from another angle.

FIG. 3 is an isometric view of the supporting bracket of FIG. 1.

FIG. 4 is an isometric view of the locating bracket of FIG. 1.

FIG. 5 is an assembled view of the mounting apparatus for the bracket of FIG. 1, viewed from one angle.

FIG. 6 is an assembled view of the mounting apparatus for the bracket of FIG. 1, viewed from another angle.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “outside” refers to a region that is beyond the outermost confines of a physical object. The term “inside” indicates that at least a portion of a region is partially contained within a boundary formed by the object. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like.

The present disclosure is described in relation to a mounting apparatus for bracket including a computer case, a supporting bracket, and a locating bracket mounted to the computer case. The computer case can include a first limiting slot and two engaging portions. The supporting bracket can include an elastic tab, two cutouts and two second limiting slots. The second limiting slot can include a guiding slot and a receiving slot. The locating bracket can include two resisting portions. The resisting portion can include a first supporting portion and a second supporting portion. The elastic tab can be rotated to slide in the first limiting slot. The two engaging portions can be locked in the cutouts. The second supporting portion can slide in the guiding slot from the receiving slot. The first supporting portion can be received in the receiving slot and can resist against the connecting plate.

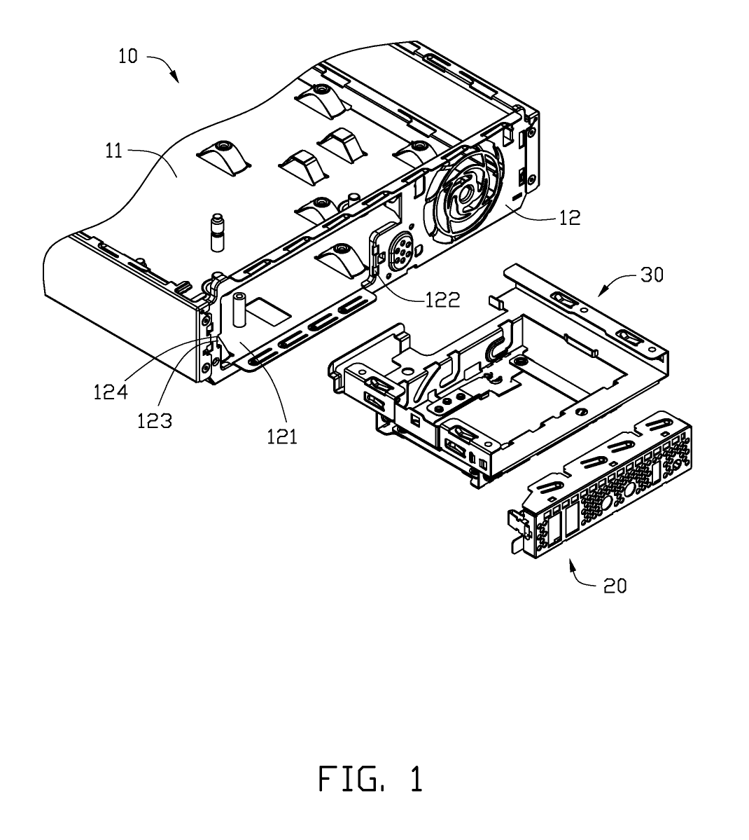

FIG. 1 illustrates a mounting apparatus for a bracket of the embodiment. The mounting apparatus can include a computer case 10 and a supporting bracket 20 mounted to the computer case 10.

The computer case 10 can include a base plate 11 and a front plate 12 substantially perpendicular to the base plate 11. A substantially rectangular opening 121 can be defined in the front plate 12. Two pivoting slots 122 can be defined in the front plate 12 on one side of the opening 121. A first limiting slot 123 is defined in the front plate 12 on another side of the opening 121. Two rectangular engaging portions 124 can be located at two corners in the first limiting slot 123.

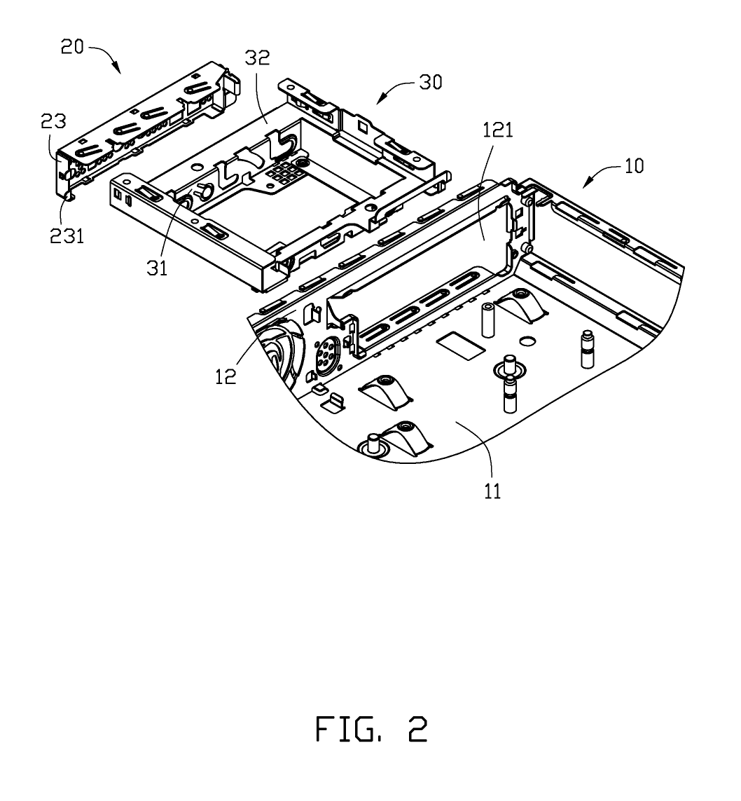

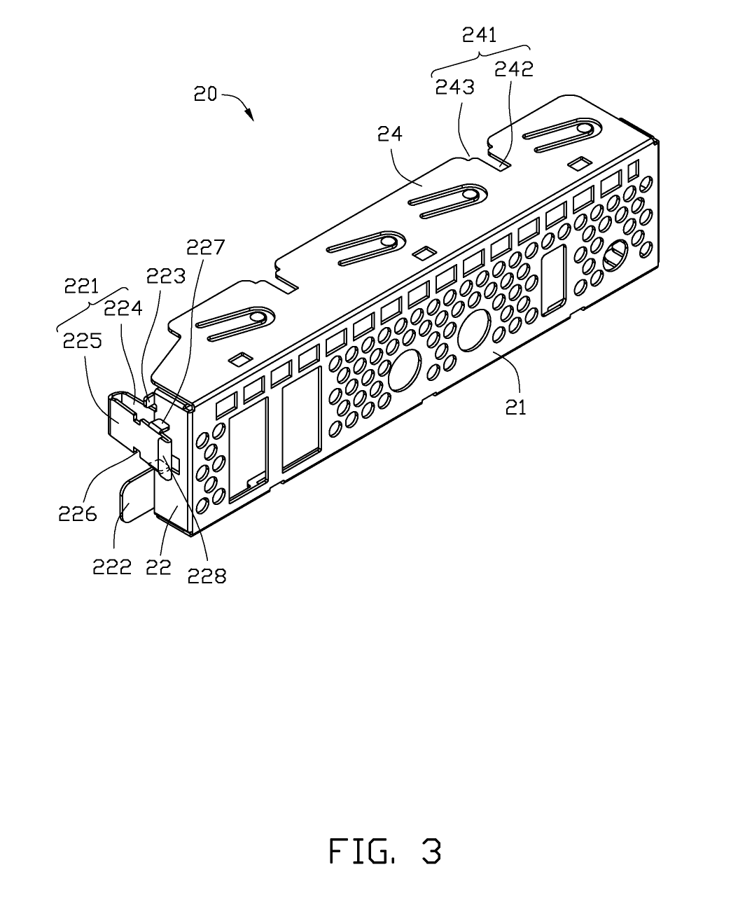

FIGS. 2 and 3 illustrate that the supporting bracket 20 can include a cover plate 21. A first side plate 22 substantially perpendicularly extends from one side of the cover plate 21. A second side plate 23 substantially perpendicularly extends from another side of the cover plate 21. A connecting plate 24 substantially perpendicularly extends from a top of the cover plate 21. The connecting plate 24 can couple with the first side plate 22 and the second side plate 23. An elastic tab 221 can bend from the first side plate 22. A first limiting plate 222 substantially perpendicularly extends from one side of the elastic tab 221. A second limiting plate 223 substantially perpendicularly extends from another side of the elastic tab 221. In at least one embodiment, a width of the first limiting plate 222 can be substantially greater than a width of the second limiting plate 223.

The elastic tab 221 can include a first bending portion 224 extending from the first side plate 22 and a second bending portion 225 diagonally extending from a distal end of the first bending portion 224. Two rectangular cutouts 226 can be defined in two sides of the second bending portion 225. Two rectangular limiting portions 227 substantially perpendicularly extend from two sides of the second bending portion 225 adjacent to the two cutouts 226 respectively. In at least one embodiment, a length of each of the two cutouts 226 can be substantially equal to a thickness of each of the two engaging portions 124. A distance between the first bending portion 224 and the second bending portion 225 is substantially greater than a width of each of the two limiting portions 227.

An operation portion 228 can protrude from a distal end of the second bending portion 225. Two pivoting plates 231 substantially perpendicularly extend from one side of the second side plate 23. Two second limiting slots 241 can be defined in the connecting plate 24. Each of the two second limiting slots 241 can include a rectangular guiding slot 242 and a receiving slot 243 communicating with the guiding slot 242. In at least one embodiment, a width of each of the two pivoting plates 231 can be substantially equal to a width of each of the two pivoting slots 122. A width of the guiding slot 242 can be substantially less than a width of the receiving slot 243.

A locating bracket 30 can be mounted to the base plate 11. The locating bracket 30 can include a supporting plate 31 and a resisting plate 32 substantially perpendicular to the supporting plate 31. Two resisting portions 321 can extend from the resisting plate 32. Each of the two resisting portions 321 can include a first supporting portion 322 substantially perpendicularly extending from the resisting plate 32, a second supporting portion 323 diagonally extending from the resisting plate 32, and a connecting portion 324 coupled to the first supporting portion 322 and the second supporting portion 323.

In at least one embodiment, a width of the first supporting portion 322 can be substantially equal to a width of the connecting portion 324. A width of the second supporting portion 323 can be substantially equal to the width of the guiding slot 242. The width of the second supporting portion 323 can be substantially less than the width of the first supporting portion 322 and the width of the connecting portion 324. The width of the receiving slot 243 can be substantially greater than the width of the first supporting portion 322 and the width of the connecting portion 324.

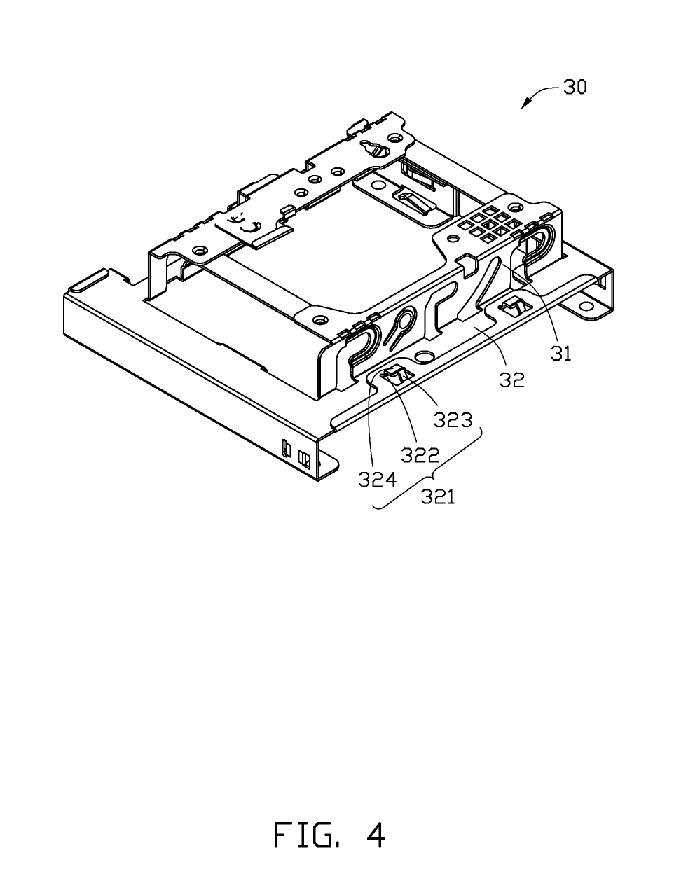

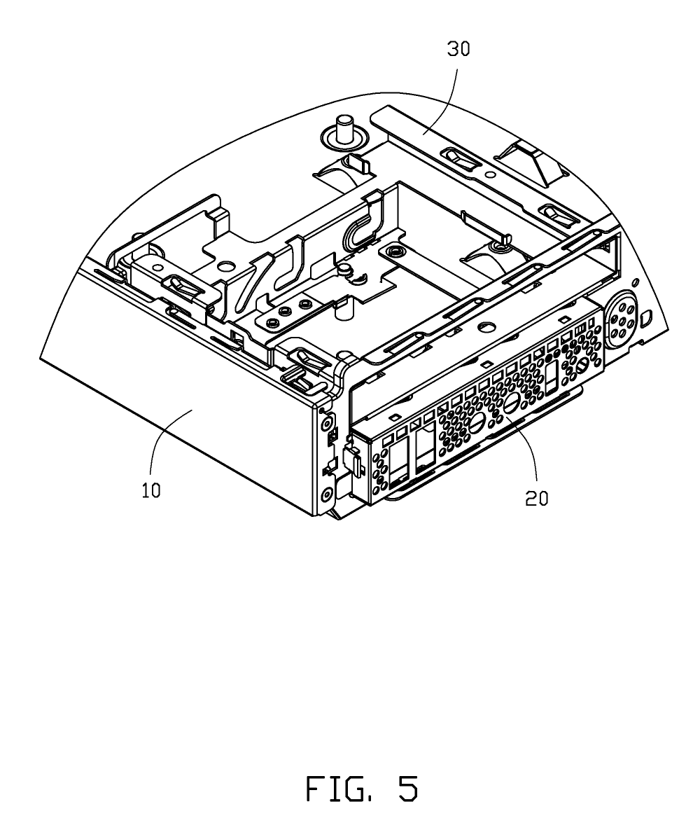

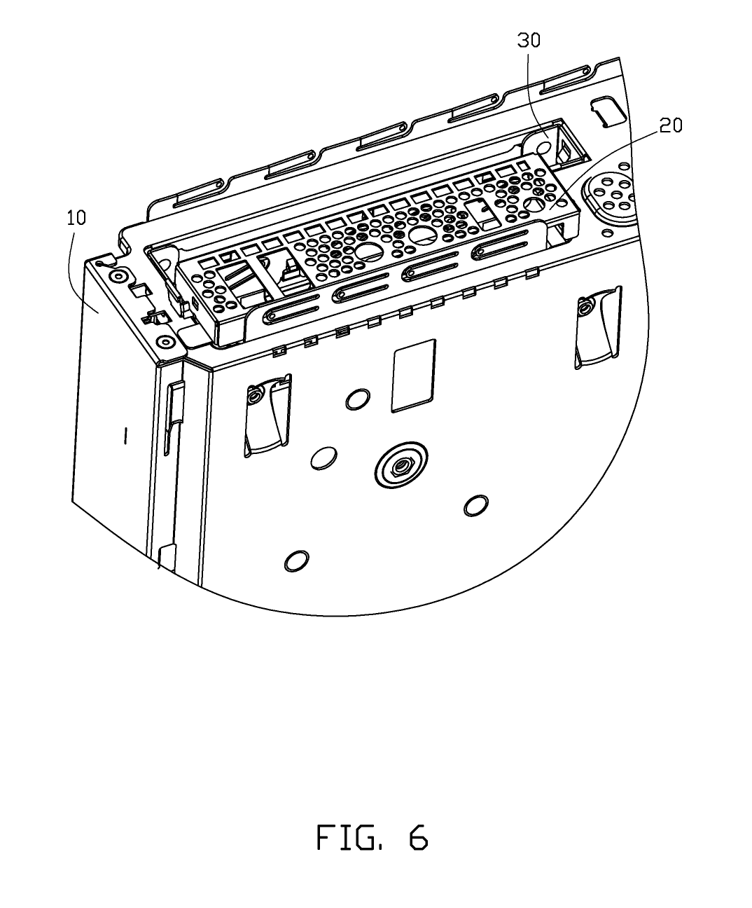

FIGS. 1 to 6 illustrate that, in assembly, the locating bracket 30 can be mounted to the base plate 11 of the computer case 10. The two pivoting plates 231 of the supporting bracket 20 can be inserted in the two pivoting slots 122 in the computer case 10. The operation portion 228 on the second bending portion 225 can move toward the first limiting slot 123. The supporting bracket 20 can rotate around the two pivoting plates 231 and the two pivoting slots 122. The first bending portion 224 and the second bending portion 225 can slide in the first limiting slot 123. The second bending portion 225 can be elastically deformed. The second supporting portion 323 can slide in the corresponding guiding slot 242 from the receiving slot 243. The first supporting portion 322 is received in the receiving slot 243 and can resist against the connecting plate 24.

The supporting bracket 20 can rotate until the two engaging portions 124 can be locked in the corresponding cutouts 226. The second bending portion 225 can be elastically returned. The first limiting plate 222 and the second limiting plate 223 can resist against the front plate 12. The supporting bracket 20 can be pivotably attached to the computer case 10 and the locating bracket 30. The two limiting portions 227 can resist against the first side plate 22 preventing the second bending portion 225 from being elastically deformed excessively. Therefore, a failure of the second bending portion 225 can be avoided.

In disassembly, the operation portion 228 can be pressed toward the first side plate 22 to elastically deform the second bending portion 225. The two engaging portions 124 can move out of the corresponding cutouts 226. The operation portion 228 can be moved away from the first limiting slot 123 around the two pivoting plates 231 and the two pivoting slots 122. The first bending portion 224 and the second bending portion 225 can slide out of the first limiting slot 123. The second bending portion 225 can be elastically returned. The second supporting portion 323 and the first supporting portion 322 can slide out from the guiding slot 242 and the receiving slot 243 respectively. The two pivoting plates 231 can be moved out of the corresponding pivoting slots 122. The supporting bracket 20 can be detached from the computer case 10 and the locating bracket 30.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A mounting apparatus for bracket, comprising:
a computer case comprising two pivoting slots and a first limiting slot with two engaging portions being located in the first limiting slot;
a supporting bracket mounted to the computer case with an elastic tab and two pivoting plates being located on the supporting bracket;
two cutouts being defined in the elastic tab;
two second limiting slots being defined in the supporting bracket, wherein each of the two second limiting slots comprises a guiding slot and a receiving slot;
a locating bracket mounted to the computer case; and
two resisting portions located on the locating bracket, wherein each of the two resisting portions comprises a first supporting portion and a second supporting portion, the two pivoting plates of the supporting bracket are inserted in the two pivoting slots in the computer case, the elastic tab rotates around the two pivoting plates and the two pivoting slots, the elastic tab slides in the first limiting slot, the elastic tab is elastically deformed, the two engaging portions are locked in the corresponding cutouts, the second supporting portion slides in the corresponding guiding slot from the receiving slot, and the first supporting portion is received in the receiving slot and resists against the connecting plate.

2. The mounting apparatus for bracket of claim 1, wherein a width of each of the two pivoting plates is substantially equal to a width of each of the two pivoting slots; and a length of each of the two cutouts is substantially equal to a thickness of each of the two engaging portions.

3. The mounting apparatus for bracket of claim 1, wherein each of the two resisting portions further comprises a connecting portion connected to the first supporting portion and the second supporting portion; a width of the first supporting portion is substantially equal to a width of the connecting portion; and a width of the second supporting portion is substantially less than the width of the connecting portion.

4. The mounting apparatus for bracket of claim 1, wherein a width of the guiding slot is substantially less than a width of the receiving slot; the width of the guiding slot is substantially equal to a width of the second supporting portion; and the width of the receiving slot is substantially greater than the width of the first supporting portion.

5. The mounting apparatus for bracket of claim 1, wherein the elastic tab comprises a first bending portion and a second bending portion extending from the first bending portion; the two cutouts are defined in the second bending portion; and when the elastic tab slides in the first limiting slot, the second bending portion is elastically deformed until the two engaging portions are locked in the corresponding cutouts.

6. The mounting apparatus for bracket of claim 5, wherein two limiting portions extends from two sides of the second bending portion adjacent to the two cutouts respectively; and the two limiting portions resist against the supporting bracket to prevent the second bending portion being elastically deformed excessively.

7. The mounting apparatus for bracket of claim 6, wherein a distance between the first bending portion and the second bending portion is substantially greater than a width of each of the two limiting portions.

8. The mounting apparatus for bracket of claim 1, wherein a first limiting plate extends from one side of the elastic tab; a second limiting plate extends from another side of the elastic tab; and when the elastic tab slides in the first limiting slot, the second bending portion is elastically deformed until the first limiting plate and the second limiting plate resists against the computer case.

9. The mounting apparatus for bracket of claim 8, wherein a width of the first limiting plate is substantially greater than a width of the second limiting plate.

10. A mounting apparatus for bracket, comprising:
a computer case comprising two pivoting slots and a first limiting slot with two engaging portions being located in the first limiting slot;
a supporting bracket mounted to the computer case with an elastic tab and two pivoting plates being located on the supporting bracket; wherein the elastic tab comprises a first bending portion and a second bending portion extending from the first bending portion;
two cutouts being defined in the second bending portion;
two second limiting slots being defined in the supporting bracket; wherein each of the two second limiting slots comprises a guiding slot and a receiving slot;
a locating bracket mounted to the computer case; and
two resisting portions located on the locating bracket; wherein each of the two resisting portions comprises a first supporting portion and a second supporting portion; the two pivoting plates of the supporting bracket are inserted in the two pivoting slots in the computer case; the elastic tab rotates around the two pivoting plates and the two pivoting slots; the elastic tab slides in the first limiting slot; the second bending portion is elastically deformed; the two engaging portions are locked in the corresponding cutouts; the second supporting portion slides in the corresponding guiding slot from the receiving slot; and the first supporting portion is received in the receiving slot and resists against the connecting plate.

11. The mounting apparatus for bracket of claim 10, wherein a width of each of the two pivoting plates is substantially equal to a width of each of the two pivoting slots; and a length of each of the two cutouts is substantially equal to a thickness of each of the two engaging portions.

12. The mounting apparatus for bracket of claim 10, wherein each of the two resisting portions further comprises a connecting portion connected to the first supporting portion and the second supporting portion; a width of the first supporting portion is substantially equal to a width of the connecting portion; and a width of the second supporting portion is substantially less than the width of the connecting portion.

13. The mounting apparatus for bracket of claim 10, wherein a width of the guiding slot is substantially less than a width of the receiving slot; the width of the guiding slot is substantially equal to a width of the second supporting portion; and the width of the receiving slot is substantially greater than the width of the first supporting portion.

14. The mounting apparatus for bracket of claim 10, wherein two limiting portions extends from two sides of the second bending portion adjacent to the two cutouts respectively; and the two limiting portions resist against the supporting bracket to prevent the second bending portion being elastically deformed excessively.

15. The mounting apparatus for bracket of claim 14, wherein a distance between the first bending portion and the second bending portion is substantially greater than a width of each of the two limiting portions.

16. The mounting apparatus for bracket of claim 10, wherein a first limiting plate extends from one side of the elastic tab; a second limiting plate extends from another side of the elastic tab; and when the elastic tab slides in the first limiting slot, the second bending portion is elastically deformed until the first limiting plate and the second limiting plate resists against the computer case.

17. The mounting apparatus for bracket of claim 16, wherein a width of the first limiting plate is substantially greater than a width of the second limiting plate.
